(19) United States
(12) Patent Application Publication
(10) Pub. No.: US 2010/0259991 A1
(43) Pub. Date: Oct. 14, 2010

(54) Nonvolatile memory cell and method for producing the same

(75) Inventor: Takamitsu Suzuki, Osaka-shi (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/659,966

(22) Filed: Mar. 26, 2010

(30) Foreign Application Priority Data
Apr. 10, 2009 (JP) 2009-096088

(51) Int. Cl. G11C 16/02; H01L 29/792; H01L 21/28

(52) U.S. Cl. 365/185.18; 257/324; 438/591; 257/E29.309; 257/E21.21

(57) ABSTRACT

A nonvolatile memory cell comprising a semiconductor substrate, a gate electrode formed on a surface of the semiconductor substrate with a gate insulation film interposed between them, a pair of impurity diffusion layers formed in a surface layer of the semiconductor substrate on both sides of the gate electrode, a channel region positioned in the surface layer of the semiconductor substrate between the pair of impurity diffusion layers, a charge storage layer formed on a surface of at least one impurity diffusion layer and along a side wall of the gate electrode, and a charge storage layer electrode laminated on the charge storage layer.

### CROSS-REFERENCE TO RELATED APPLICATION

This application is related to Japanese patent application No. 2009-096088 filed on Apr. 10, 2009 whose priority is claimed under 35 USC §119, the disclosure of which is incorporated by reference in its entirety.

### BACKGROUND OF THE INVENTION

1. Field of the Invention

The present invention relates to a nonvolatile memory cell and a method for producing such a nonvolatile memory cell, and more particularly to a nonvolatile memory cell possessing an improved writing efficiency.

2. Description of the Related Art

Recently, as computer data storage capacity increases, a nonvolatile semiconductor memory device is required to have further large capacity. There are two principal methods for implementing this requirement as follows.

According to a first method, four or more-value data is stored in one transistor by controlling a charge amount stored in a charge storage layer (floating gate, for example) of a nonvolatile memory cell, and providing four or more regions for controlling a transistor threshold voltage.

According to a second method, a memory capacity per transistor is substantially increased by providing a plurality of charge storage layers in one transistor physically. As one of the second method, Japanese Unexamined Patent Publication No. 2003-332474 discloses a nonvolatile memory cell having two-bit memory capacity per transistor by forming a charge storage layer along each side wall of a gate electrode of the transistor.

FIG. 17 of Japanese Unexamined Patent Publication No. 2003-332474 is a schematic cross-sectional view of the conventional nonvolatile memory cell.

This nonvolatile memory cell (hereinafter, simply referred to as the “memory cell” occasionally) includes a gate electrode 102 formed on a surface of a semiconductor substrate 100 with an insulation film 101 interposed between them, first and second impurity diffusion layers 103a and 103b formed in a surface part of the semiconductor substrate 100 on both sides of the gate electrode 102, a channel region 104 formed between the first and second impurity diffusion layers 103a and 103b, and a charge storage layer 105 formed on each of the impurity diffusion layers 103a and 103b and along each side wall of the gate electrode 102.

The charge storage layer 105 is an ONO film in which a silicon oxide film 105a, a silicon nitride film 105b, and a silicon oxide film 105c are laminated in this order and is formed into a shape of a sidewall spacer.

At a time of writing into this memory cell, the first impurity diffusion layer 103a is used as a source region, and the second impurity diffusion layer 103b is used as a drain region, and data is written in the charge storage layer 105 adjacent to the second impurity diffusion layer, for example. As its voltage condition, 0V is applied to the first impurity diffusion layer 103a and the semiconductor substrate 100, +5V is applied to the second impurity diffusion layer 103b, and +6V is applied to the gate electrode 102, for example. In addition, the term “writing” in this specification means a process for injecting an electron into the charge storage layer 105.

In this voltage condition, an inversion layer is generated from the first impurity diffusion layer 103a to the channel region 104, but the inversion layer does not reach the second impurity diffusion layer 103b, and a pinch-off point is generated at an end of the inversion layer on the side of the second impurity diffusion layer 103b.

The electron is accelerated from the pinch-off point toward the second impurity diffusion layer 103b by a high electric field and becomes so-called a hot electron (high-energy conduction electron). This hot electron is induced by a vertical electric field ranging from the semiconductor substrate 100 to the gate electrode 102 and injected into the silicon nitride film 105b of the charge storage layer 105 adjacent to the second impurity diffusion layer 103b, whereby the writing is performed.

However, the memory cell shown in FIG. 17 has a problem that writing efficiency to the charge storage layer 105 is low, and a writing time is long.

Therefore, in an array structure having the plurality of memory cells, a writing time for a whole memory cell array increases, and it could become an unrealistic writing time. In addition, when data is written into the charge storage layer 105 adjacent to the first impurity diffusion layer 103a, the first impurity diffusion layer 103a is used as the drain region, and the second impurity diffusion layer 103b is used as the source region by reversing the first impurity diffusion layer 103a and the second impurity diffusion layer 103b in the above voltage condition, but in this case also, a writing time is problematically long.

### SUMMARY OF THE INVENTION

The present inventor found that the problem that the writing efficiency of the conventional nonvolatile memory cell is low depends on a weak electric field component to accelerate and induce the hot electron toward the charge storage layer 105, and reached the present invention.

Therefore, the present invention was made in view of the above problem and it is a primary object of the present invention to provide a nonvolatile memory cell capable of increasing operation speed, and a method for producing such a nonvolatile memory cell.

Thus, according to the present invention, there is provided a nonvolatile memory cell comprising a semiconductor substrate, a gate electrode formed on a surface of the semiconductor substrate with a gate insulation film interposed between them, a pair of impurity diffusion layers formed in a surface layer of the semiconductor substrate on both sides of the gate electrode, a channel region positioned in the surface layer of the semiconductor substrate between the pair of impurity diffusion layers, a charge storage layer formed on a surface of at least one impurity diffusion layer and along a side wall of the gate electrode, and a charge storage layer electrode laminated on the charge storage layer.

In addition, according to another aspect of the present invention, there is provided a method for producing a nonvolatile memory cell comprising the steps of forming a gate electrode on a surface of a semiconductor substrate with a gate insulation film interposed between them, forming a pair of impurity diffusion layers in a surface layer of the semiconductor substrate on both sides of the gate electrode, forming a charge storage layer on a surface of at least one impurity diffusion layer and along a side wall of the gate electrode, and laminating a charge storage layer electrode on the charge storage layer.

In the nonvolatile memory cell according to the present invention, since the charge storage layer electrode is laminated on the charge storage layer, an electric field generated upward from the semiconductor substrate is applied to the charge storage layer at the time of writing. As a result, a hot electron generated in the vicinity of the semiconductor substrate and the one impurity diffusion layer (drain region) is efficiently injected into the charge storage layer, whereby writing efficiency is improved and a writing time is considerably shortened.

### BRIEF DESCRIPTION OF THE DRAWINGS

FIG. 1 is a plan view showing a first embodiment of a nonvolatile semiconductor memory device including a nonvolatile memory cell according to the present invention;

FIG. 2 is a vertical cross-sectional view taken along a line X1 in FIG. 1;

FIG. 3 is a partial cross-sectional view showing a production step of the nonvolatile memory cell according to the present invention;

FIG. 4 is a partial cross-sectional view showing the next step of FIG. 3;

FIG. 5 is a partial cross-sectional view showing the next step of FIG. 4;

FIG. 6 is a partial cross-sectional view showing the next step of FIG. 5;

FIG. 7 is a partial cross-sectional view showing the next step of FIG. 6;

FIG. 8 is a partial cross-sectional view showing the next step of FIG. 7;

FIG. 9 is a partial cross-sectional view showing the next step of FIG. 8;

FIG. 10 is a plan view showing a second embodiment of a nonvolatile semiconductor memory device including a nonvolatile memory cell according to the present invention;

FIG. 11 is a vertical cross-sectional view taken along a line X2 in FIG. 10;

FIG. 12 is a plan view showing a third embodiment of a nonvolatile semiconductor memory device including a nonvolatile memory cell according to the present invention;

FIG. 13 is a vertical cross-sectional view taken along a line X3 in FIG. 12;

FIG. 14 is a partial plan view showing a fourth embodiment of a nonvolatile semiconductor memory device including a nonvolatile memory cell array according to the present invention;

FIG. 15 is a vertical cross-sectional view taken along a line X4 in FIG. 14;

FIG. 16 is a schematic block diagram showing a mobile telephone serving as a portable electronic device including the nonvolatile memory cell according to the present invention; and

FIG. 17 is a schematic cross-sectional view of a conventional nonvolatile memory cell disclosed in Japanese Unexamined Patent Publication No. 2003-332474.

### DETAILED DESCRIPTION OF THE PREFERRED EMBODIMENTS

A nonvolatile memory cell (hereinafter, simply referred to as the “memory cell” occasionally) according to the present invention includes a semiconductor substrate, a gate electrode formed on a surface of the semiconductor substrate with a gate insulation film interposed between them, a pair of impurity diffusion layers formed in a surface layer of the semiconductor substrate on both sides of the gate electrode, a channel region positioned in the surface layer of the semiconductor substrate between the pair of impurity diffusion layers, a charge storage layer formed at least on a surface of one impurity diffusion layer and along a side wall of the gate electrode, and a charge storage layer electrode laminated on the charge storage layer.

At a time of operation of the memory cell, one of the pair of impurity diffusion layer functions as a source region or a drain region and the other thereof functions as the drain region or the source region.

In this memory cell, writing, reading, or erasing can be performed by applying predetermined voltages to the semiconductor substrate, the gate electrode, the pair of impurity diffusion layers, and the charge storage layer electrode.

A voltage to the charge storage layer electrode can be controlled independently from a voltage to the impurity diffusion layer adjacent to the charge storage layer electrode, so that the voltage to the charge storage layer electrode may be different from or the same as that of the voltage applied to the adjacent impurity diffusion layer, or may be different from or the same as that of the voltage applied to the gate electrode as long as the operation (writing, reading, or erasing) can be appropriately performed.

Writing efficiency of the memory cell depends on a film thickness of the charge storage layer and a voltage condition.

When an electric field generated by a voltage applied to the charge storage layer electrode through the charge storage layer is too strong, an electric field at a junction part between the impurity diffusion layer (drain region) to which the electron is injected and the semiconductor substrate is weakened, so that efficiency of hot electron generation is lowered, but when the electric field is too weak, efficiency of electron injection to the charge storage layer is lowered, so that in both cases, the writing efficiency is lowered.

Therefore, it is preferable to set an optimal writing voltage condition based on the film thickness of the charge storage layer.

On the other hand, at the time of erasing, in the case where a negative voltage is applied to the gate electrode and a positive voltage is applied to the drain region to write a hot hole, erasing speed is higher when the negative voltage is applied to the charge storage layer electrode than when the positive voltage is applied thereto. In addition, the erasing can be also performed by applying the positive voltage to both of the drain region and the charge storage layer electrode, but the erasing speed decreases as compared with the above case. However, merit of high writing speed is to be more valued than demerit of low erasing speed.

In addition, at the time of reading, its efficiency is hardly affected.

This memory cell may be configured according to the following requirements (1) to (10).

(1) The charge storage layer electrode is electrically connected to the adjacent impurity diffusion layer.

In this case, an electrode structure can be simplified and favorable because the same voltage is applied to the charge storage layer and its adjacent impurity diffusion layer, and production steps and cost of the memory cell are reduced, and voltage control at the time of memory cell operation can be easy. In addition, since a cell area reduces, the cost is reduced.

(2) The impurity diffusion layer adjacent to the charge storage layer electrode is arranged apart from a region just under the gate electrode in a channel length direction, whereby an offset region is formed in the channel region. That is, this “offset region” is a region in the semiconductor substrate surface part positioned between the region just under the gate electrode in the channel region and the impurity diffusion layer.

When the offset region is provided, inversion facility in the offset region when a voltage is applied to the gate electrode can be considerably varied by a charge amount stored in the charge storage layer, so that a memory effect can be enhanced. Consequently, large hysteresis (variation in threshold value) can be obtained.

Furthermore, since a short channel effect can be efficiently prevented as compared with a general logic transistor, a gate length can be further miniaturized. In addition, since the offset region can be easily formed in this memory cell in view of its structure, and prevent the short channel effect, a thick gate insulation film can be used as compared with the logic transistor, so that reliability can be improved.

Since a dimension of the offset region in the channel length direction affects the enhancement of the memory effect and the prevention of the short channel effect, it is preferably adjusted according to need. When the dimension of the offset region is too small, the memory effect cannot be obtained, and the short channel effect cannot be prevented, but when it is too large, a drain current is considerably reduced, so that reading speed becomes considerably low and miniaturization of the memory cell is limited.

Therefore, the dimension of the offset region in the channel length direction is preferably decided with a view to obtaining enough hysteresis and preferable reading speed, and preferably as 10 to 100 nm. However, the dimension of the offset region depends on a film thickness of the charge storage layer extending along the side wall of the gate electrode in some cases, depending on production steps of the memory cell.

In addition, although the memory cell can be operated even when the impurity diffusion layer overlaps the region just under the gate electrode (the offset region is not provided), the offset region is preferably to be provided when a greater memory hysteresis effect is needed.

(3) When the channel region has the offset region like in (2), the charge storage layer electrode is formed such that the electric field is generated at least in a part of the charge storage layer which overlaps the offset region. More specifically, at the time of writing, since charges are mainly stored at least in the part of the charge storage layer overlapping the offset region, a size, shape, position and the like of the charge storage layer electrode are determined such that the electric field is generated at least in this part.

In addition, the charge storage layer electrode may be formed into a sidewall spacer shape of the gate electrode with the charge storage layer, because in this case, it is easily produced, and prevented from coming off the charge storage layer.

(4) Since a part of the charge storage layer overlapping the impurity diffusion layer affects operation efficiency of the writing and erasing, it may be appropriately adjusted according to need, but when it is too short, the operation efficiency is lowered. Therefore, the overlapping part starting from an end of the impurity diffusion layer on the side of the channel region to the channel length direction preferably has a length of 100 nm or more, and more preferably has a length of 100 to 300 nm in view of the miniaturization of the memory cell.

In addition, even when the charge storage layer completely covers the impurity diffusion layer in the channel length direction, there is no problem in particular, but when the charge storage layer electrode is electrically in contact with the impurity diffusion layer like in the above case, a through hole is formed to expose the impurity diffusion layer in the contact part in some cases.

(5) The charge storage layer may have the following laminated structures (A) and (B).

(A) The charge storage layer is composed of one or more unit laminated films each having a first insulation film and a second insulation film formed in this order.

(B) The charge storage layer is composed of one or more unit laminated films each having a first insulation film and a second insulation film and a third insulation film formed in this order.

The first insulation film functions as a tunnel insulation film, and may be an insulation film such as silicon oxide film or silicon nitride film, a high-dielectric-constant oxide thin film such as aluminum oxide film, titanium oxide film, tantalum oxide film, or hafnium oxide film, or a laminated film of these insulation films. When a silicon substrate is used as the semiconductor substrate, the silicon oxide film is preferably used as the first insulation film.

The second insulation film functions to trap the charge (electron or hole) in a trap level and store it, and may be an insulation film such as silicon nitride film or silicon oxide film, or a high-dielectric-constant oxide thin film such as aluminum oxide film, titanium oxide film, tantalum oxide film, or hafnium oxide film. Among them, the silicon nitride film is preferably used because enough trap level density can be provided and its formation process is easy.

The third insulation film functions to prevent the charge trapped in the trap level from escaping from the second insulation film, and may be a single layer film or laminated film formed of the same material or a different material in the various materials for the first insulation film. When the silicon oxide film is used as the first insulation film, the silicon oxide is preferably used also as the third insulation film because its formation process is easy.

When the unit laminated film is one layer of the laminated structure (A), the second insulation film is an outermost layer, so that the charge storage layer electrode is laminated on the second insulation film.

When the charge is stored in the second insulation film, the charge is trapped in the trap levels scattered in the second insulation film, so that as long as the electric field in the charge storage layer is not large, the trapped charge does not escape from the trap level even though the second insulation film is in contact with the charge storage layer electrode.

The case where the unit laminated film is one layer of the laminated structure (A) has a merit of only needing the small number of steps when the charge storage layer is formed.

When the unit laminated film is more than one layer of the laminated structure (A), since the charge storage layer has a structure in which the inner second insulation film which traps the charge in the trap level is sandwiched between the inner first insulation film and the outer first insulation film, the charge is prevented from escaping from the inner second insulation layer even when the electric field in the charge storage layer is large, so that data is prevented from being varied and reliability is improved, and an enough retention time can be ensured.

In addition, the term “inner” means the side of the semiconductor substrate and the side of the gate electrode, and the term “outer” means the opposite side of the “inner” side.

When the unit laminated film is one or more layers of the laminated structure (B), the charge storage layer has a structure in which the inner second insulation film which traps the charge in the trap level, is sandwiched between the inner first insulation film and the outer third insulation film, so that the charge is prevented from escaping from the inner second insulation layer even when the electric field in the charge storage layer is large, so that data is prevented from being varied and reliability is improved, and an enough retention time can be ensured. In addition, the case where the unit laminated film is one layer of the laminated structure (B) has a merit of only needing the small number of steps when the charge storage layer is formed.

In those laminated structures (A) and (B), since film thicknesses of the first to third insulation films are elements to determine writing efficiency, erasing efficiency and reliability, they are to be appropriately adjusted according to need such that the first insulation film is 20 nm or less, the second insulation film is about 5 to 100 nm, and the third insulation film is about 5 to 100 nm.

(6) The charge storage layer electrode is not limited in particular as long as it can be used in the general semiconductor device, and may be a conductive film or laminated film formed of polysilicon, metal such as copper or aluminum, high melting point metal such as tungsten, titanium, or tantalum, or silicide with high melting point metal. In view of processability, polysilicon is preferably used by injecting the same conductivity type impurity as that of the impurity diffusion layer.

(7) The charge storage layer and the charge storage layer electrode may be arranged on each side of the gate electrode.

In this case, the memory cell has two-bit memory capacity per transistor.

(8) The semiconductor substrate is not limited in particular as long as it can be used in the semiconductor device, and may be such as a bulk substrate composed of an elementary semiconductor such as silicon or germanium and a compound semiconductor such as SiGe, GaAs, InGaAs, ZnSe, or GaN, an SOI (silicon on insulator) substrate having a surface semiconductor layer, or a multilayer SOI substrate. Among them, the silicon substrate is preferably used in view of easiness in production.

In addition, the semiconductor substrate may have a first conductivity type (P type or N type), or may have at least one well region having a second conductivity type (N type or P type). Impurity concentrations of the semiconductor substrate and its well region may be set within a well-known range in this field. Furthermore, when the SOI substrate is used as the semiconductor substrate, the well region may be formed in the surface semiconductor layer, or a body region may be provided under the channel region.

(9) The gate insulation film is not limited in particular as long as it can be used in the general semiconductor device, and may be an insulation film such as silicon oxide film or silicon nitride film, a high-dielectric-constant oxide thin film such as aluminum oxide film, titanium oxide film, tantalum oxide film, and hafnium oxide film, or laminated film of these insulation films. When the silicon substrate is used as the semiconductor substrate, the silicon oxide film is preferably used.

The gate insulation film is about 1 to 20 nm in thickness, and preferably about 1 to 6 nm in thickness.

(10) The gate electrode is not limited in particular as long as it can be used in the general semiconductor device, and may be a single layer film or laminated film formed of polysilicon, metal such as copper or aluminum, high melting point metal such as tungsten, titanium, or tantalum, or silicide with high melting point metal.

In addition, the gate electrode may have the N type or P type conductivity, and its film thickness is preferably about 50 to 400 nm.

Hereinafter, a detailed description will be made of embodiments of the nonvolatile memory cell and the method for producing such a nonvolatile memory cell according to the present invention with reference to the drawings. In addition, it is assumed that the semiconductor substrate is in a horizontal state in the following description of the embodiments.

### First Embodiment

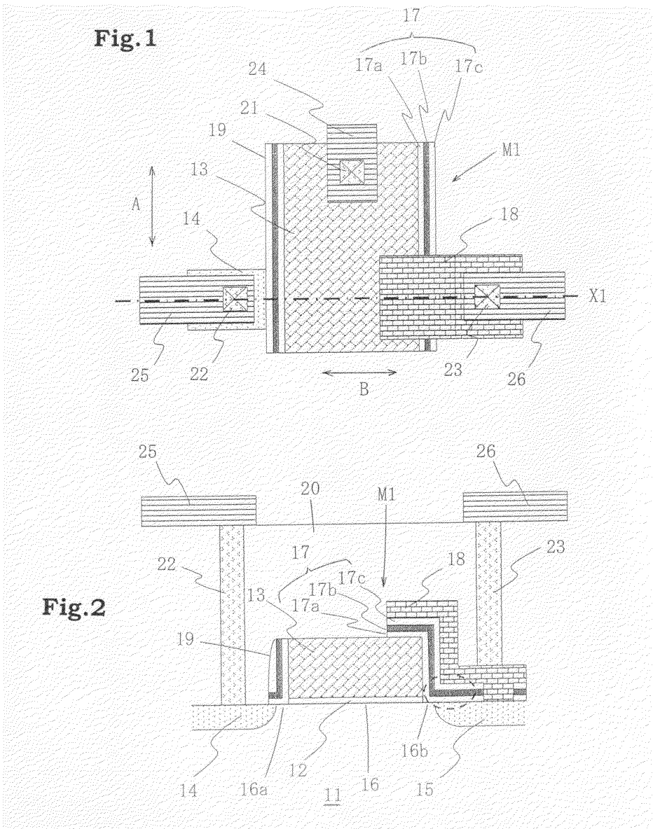

FIG. 1 is a plan view showing a first embodiment of a nonvolatile semiconductor memory device including a nonvolatile memory cell according to the present invention, and FIG. 2 is a vertical cross-sectional view taken along a line X1 in FIG. 1.

### <Memory Cell Structure>

A memory cell M1 in the first embodiment includes a semiconductor substrate 11, a gate electrode 13 formed on a surface of the semiconductor substrate 11 with a gate insulation film 12 interposed between them, a pair of impurity diffusion layers 14 and 15 formed in a surface layer of the semiconductor substrate 11 on both sides of the gate electrode 13, a channel region 16 positioned in the surface layer of the semiconductor substrate 11 between the pair of impurity diffusion layers 14 and 15, a charge storage layer 17 formed on the surface of the one impurity diffusion layer 15 and along a side wall of the gate electrode 13, and a charge storage layer electrode 18 laminated on the charge storage layer 17. In addition, a sidewall spacer 19 made of the same material as that of the charge storage layer 17 is formed along a side wall of the gate electrode 13 on the side of the other impurity diffusion layer 14.

Hereinafter, the impurity diffusion layer is simply referred to as the diffusion layer occasionally.

The nonvolatile semiconductor memory device (hereinafter, simply referred to as the “semiconductor memory device” occasionally) according to the first embodiment includes the memory cell M1, an interlayer insulation film 20 laminated on the memory cell M1, contact plugs 21, 22, and 23 buried in three contact holes formed in the interlayer insulation film 20 so as to be electrically connected to the gate electrode 13 and the pair of diffusion layers 14 and 15, respectively, and a gate wiring 24, a source wiring 25, and a drain wiring 26 formed on the interlayer insulation film 20 so as to be electrically connected to the contact plugs 21, 22, and 23, respectively.

In addition, FIG. 1 shows the memory cell M1 under the interlayer insulation film 20 fluoroscopically.

The gate insulation film 12 and the gate electrode 13 are roughly the same in size, and a width of a channel width direction A is about 50 to 500 nm, and a length of a channel length direction B is about 50 to 500 nm.

The pair of diffusion layers 14 and 15 is arranged so as to retreat from a region just under the gate electrode 13 in the channel length direction B by a predetermined dimension, and regions corresponding to this predetermined dimension are set as offset regions 16a and 16b in the channel region 16 (see FIG. 9).

A channel length dimension of the channel region 16 is about 50 to 1000 nm, a channel width dimension of the channel region 16 is about 50 to 500 nm, and a dimension L1 of the offset regions 16a and 16b in the channel length direction B is about 10 to 300 nm (see FIG. 9).

The pair of diffusion layers 14 and 15 formed in the surface layer of the semiconductor substrate 11 are provided by injecting an N conductivity type impurity such as phosphorus or arsenic in the surface of the semiconductor substrate 11 at a concentration of 1×10¹⁹ to 1×10²² cm⁻³, and ranges from the semiconductor substrate surface to about 100 to 500 nm in depth.

The charge storage layer electrode 18 is formed on the charge storage layer 17 so as to cover almost the whole one diffusion layer 15 and a part of an upper surface of the gate electrode 13 in planar view (see FIG. 1), and penetrates the charge storage layer 17 on the diffusion layer 15 so as to be electrically in contact with the diffusion layer 15.

The charge storage layer 17 is an ONO film formed such that a silicon oxide film 17a, a silicon nitride film 17b, and a silicon oxide film 17c are laminated in this order, and has a vertical part extending along the side wall of the gate electrode 13 on the side of the one diffusion layer 15, and high and low parallel parts disposed just under the charge storage layer electrode 18.

In the parallel part of the charge storage layer 17 formed along the surface of the diffusion layer 15, a part overlapping the diffusion layer 15 ranging from an end of the diffusion layer 15 on the side of the channel region 16 to the channel length direction B has a length L2 of 100 to 300 nm (see FIG. 9).

In addition, in this memory cell M1, the charge storage layer 17 and the charge storage layer electrode 18 may be arranged on the side of the diffusion layer 14 and the sidewall spacer 19 may be arranged on the side of the diffusion layer 15.

### <Method for Producing Memory Cell>

Next, a description will be made of a method for producing the memory cell M1 according to the first embodiment.

First, the gate electrode is formed on the surface of the semiconductor substrate with the gate insulation film interposed between them.

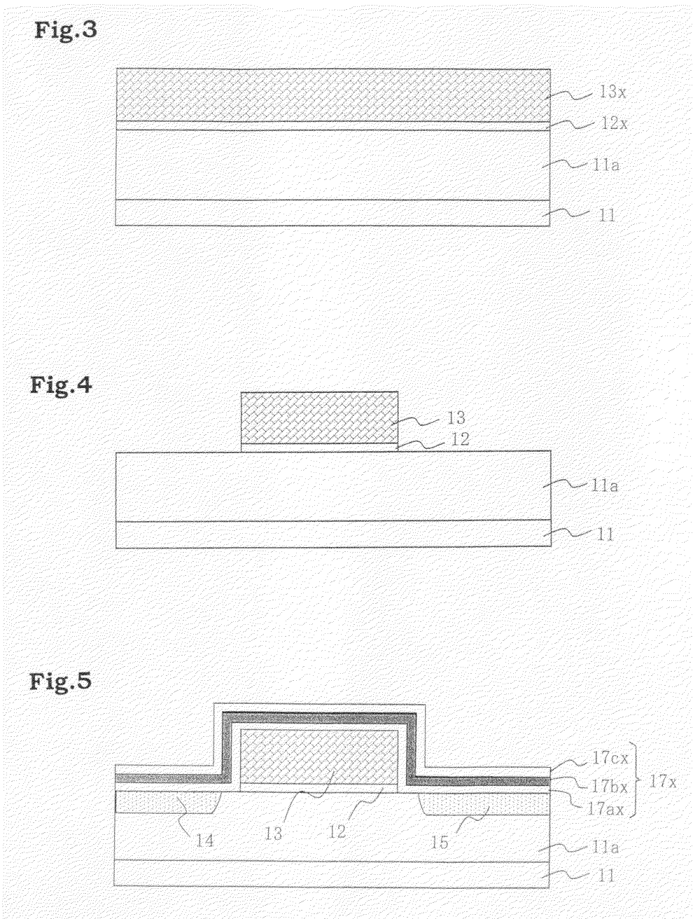

As shown in FIG. 3, in this step, a silicon oxide film 12x and a polysilicon film 13x are sequentially deposited on the P type silicon substrate (semiconductor substrate) 11 having a P type well 11a on its surface layer. The silicon oxide film 12x is formed to be about 3 to 100 nm in thickness by a well-known technique such as thermal oxidation or CVD. The polysilicon film 13x is formed to be about 50 to 500 nm in thickness by a well-known technique such as CVD or sputtering.

Then, a photoresist (not shown) having an opening to form the gate electrode is formed on the polysilicon film 13x by photolithography, and the polysilicon film 13x and the silicon oxide film 12x are removed by reactive ion etching and the like, whereby the gate insulation film 12 and the gate electrode 13 are formed on the silicon substrate 11 as shown in FIG. 4.

Then, the photoresist is removed by etching.

Next, the following steps are performed in parallel, that is, a step of forming the charge storage layer at least on the surface of one impurity diffusion layer and along the side wall of the gate electrode, a step of forming the pair of impurity diffusion layers in the surface layer of the semiconductor substrate on both sides of the gate electrode, and a step of laminating the charge storage layer electrode on the charge storage layer.

As shown in FIG. 5, in these steps, a silicon oxide film 17ax, a silicon nitride film 17bx, and a silicon oxide film 17cx are sequentially deposited on the silicon substrate 11 so as to cover the gate insulation film 12 and the gate electrode 13 by a well-known technique such as CVD, whereby an ONO film 17x is formed. At this time, a film thickness of each layer may be adjusted appropriately according to need because they are elements to determine writing efficiency and reliability, and it is preferable that the silicon oxide film 17ax is 20 nm or less in thickness, the silicon nitride film 17bx is about 5 to 100 nm in thickness, and the silicon oxide film 17cx is about 5 to 100 nm in thickness.

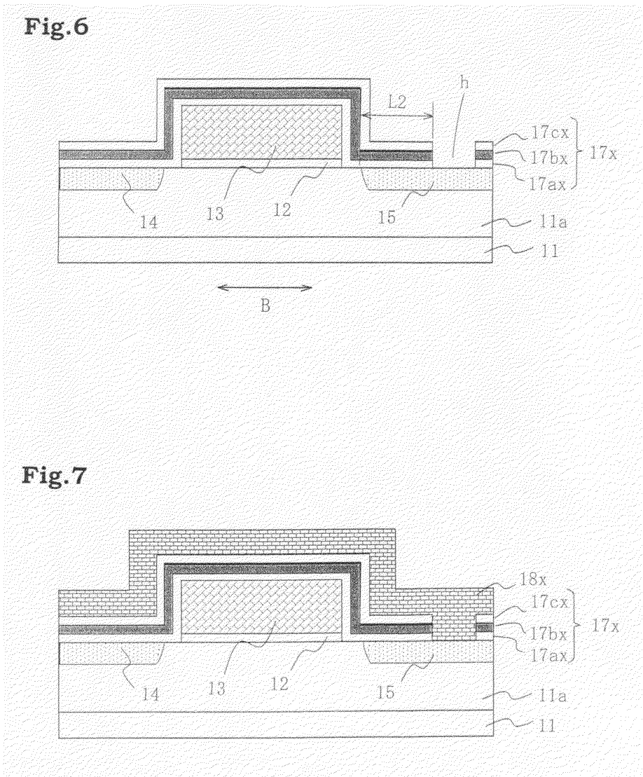

Then, as shown in FIG. 6, N⁺ impurity is injected into the surface of the silicon substrate 11 positioned on both sides of the gate electrode 13 in the channel length direction B through the ONO film 17x, whereby the N type impurity diffusion layers 14 and 15 whose conductivity type is opposite to that of the P type well 11a.

Then, as shown in FIG. 6, a photoresist (not shown) having an opening to form a contact hole is formed on the ONO film 17x by photolithography, and the silicon oxide film 17cx, the silicon nitride film 17bx and the silicon oxide film 17ax are sequentially removed by reactive ion etching or wet etching to expose a part of the one diffusion layer 15, whereby a contact hole h is formed. At this time, the contact hole h is formed such that the overlapping part of the ONO film 17x on the diffusion layer 15 has the length L2 of 100 to 300 nm in the channel length direction B.

Then, the photoresist is removed by etching.

Then, as shown in FIG. 7, a polysilicon film 18x is deposited on the ONO film 17x by a well known technique such as CVD, and an N type impurity is injected in the polysilicon film 18x. At this time, a film thickness of the polysilicon film 18x is preferably about 50 to 300 nm, and its N type impurity concentration is preferably about 10¹⁹ to 10²² cm⁻³.

A part of the polysilicon film 18x is formed in the contact hole h and electrically in contact with the diffusion layer 15.

In addition, after the N type impurity injection into the polysilicon film 18x, an annealing process is appropriately performed at about 800 to 1100° C. to reduce contact resistance between the polysilicon film 18x and the diffusion layer 15.

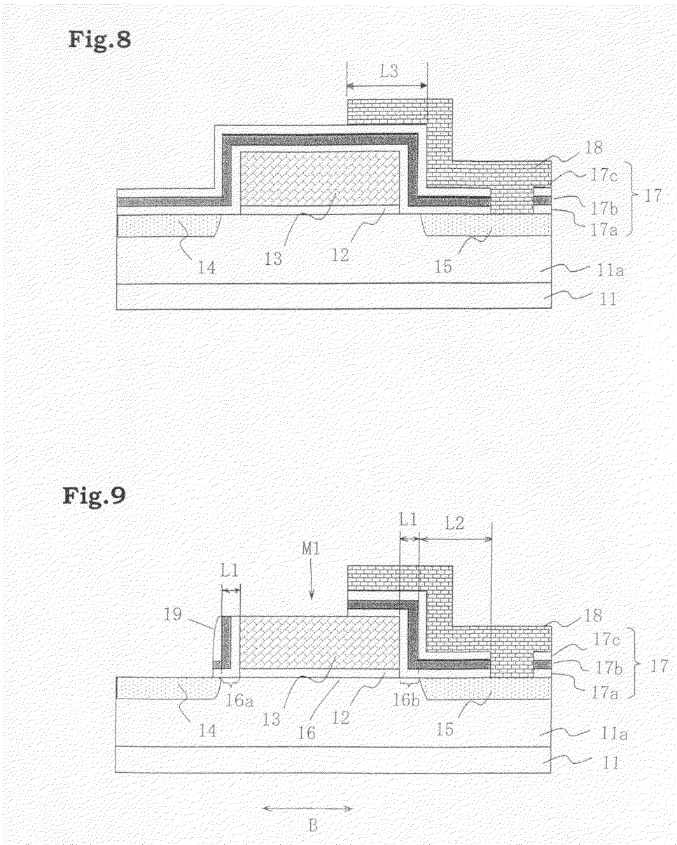

Then, a photoresist (not shown) having an opening to form the charge storage layer electrode is formed on the polysilicon film 18x by photolithography, and the polysilicon film 18x is removed by reactive ion etching or wet etching, whereby the charge storage layer electrode 18 is patterned as shown in FIG. 8.

At this time, the charge storage layer electrode 18 is patterned to have a size which covers the parallel part of the ONO film 17x which is parallel to the diffusion layer 15 and keeps in contact with the diffusion layer 15. Furthermore, in order to prevent the charge storage layer electrode 18 from removing from the vertical part of the ONO film 17x, it preferably extends on the upper surface of the gate electrode 13 in the channel length direction B by a predetermined dimension L3. This dimension L3 is preferably set to about 50 to 150 nm in view of a dimensional variation of the charge storage layer electrode 18.

Then, the photoresist is removed by etching.

Then, as shown in FIG. 9, the silicon oxide film 17cx, the silicon nitride film 17bx, and the silicon oxide film 17ax of the ONO film 17x are sequentially removed by reactive ion etching using the charge storage layer electrode 18 as a mask.

Thus, the charge storage layer 17 is patterned so as to be formed just under the charge storage layer electrode 18, and the sidewall spacer 19 is formed on the side wall of the gate electrode 13 on the side of the diffusion layer 14.

The memory cell M1 shown in FIGS. 1 and 2 is specifically formed through the above steps.

Next, a basic memory operation of the memory cell M1 will be described with reference to FIGS. 1 and 2.

### <Writing Operation of Memory Cell>

When data is written in the memory cell M1, the diffusion layer 15 adjacent to the charge storage layer 17 is set as the drain region 15, and the other diffusion layer 14 is set as the source region 14. In addition, here, the charge storage layer electrode 18 is referred to as the drain electrode 18.

At the time of writing, +6V is applied to the gate electrode 13, +5V is applied to the drain electrode 18, 0V is applied to the source region 14, and 0V is applied to the semiconductor substrate 11, for example.

In this voltage condition, an inversion layer is formed in the channel region 16 such that it extends from the source region 14 but does not reach the drain region 15, and a pinch-off point is generated. Thus, an electron moves from the source region 14 to the drain region 15 (a channel current is in the opposite direction), and channel hot electrons (CHE) are generated in the vicinity of the boundary between the drain region 15 and the channel region 16, and a part of CHE overcomes a potential barrier of the silicon oxide film 17a of the charge storage layer (ONO film) 17 on the side of the drain region 15, and trapped and retained in a trap region of the silicon nitride film 17b in a region surrounded by a dotted line in FIG. 2, whereby the data is written.

Here, when the voltage of +5V is applied to the drain electrode 18, an upward electric field about 1 MV/cm is generated through the charge storage layer 17. As a result, efficiency of the CHE injection to the charge storage layer 17 is promoted, and the writing efficiency can be improved to be 10 to 100 times as high as that of the conventional nonvolatile memory cell (see FIG. 17).

In addition, as for the memory cell (not shown) in which the charge storage layer 17 and the charge storage layer electrode 18 are arranged on the side of the diffusion layer 14, and the sidewall spacer 19 is arranged on the side of the diffusion layer 15, the diffusion layer 15 serves as the source region and the other diffusion layer 14 serves as the drain region, and similarly to the above example, +6V is applied to the gate electrode, +5V is applied to the drain electrode, 0V is applied to the source region, and 0V is applied to the semiconductor substrate, for example, whereby the data can be efficiently written.

### <Erasing Operation of Memory Cell>

At the time of erasing, −6V is applied to the gate electrode 13, 5V is applied to the charge storage layer electrode (drain electrode) 18 and the diffusion layer (drain region 15), the diffusion layer (source region) 14 is set in a floating state, and 0V is applied to the semiconductor substrate 11, for example.

In this voltage condition, the boundary region between the drain region 15 and the channel region 16 of the semiconductor substrate 11 becomes a high electric field due to the gate voltage and the drain voltage, so that an interband tunneling current is generated and a hot hole is generated. This hot hole is drawn toward the gate electrode 13, and injected to the charge storage layer 17, and coupled with the electron in the charge storage layer 17, so that erasing is performed.

### <Reading Operation of Memory Cell>

At the time of reading operation, +2V is applied to the gate electrode 13, 0V is applied to the drain electrode 18, +1V is applied to the source region 14, and 0V is applied to the semiconductor substrate 11, for example.

In this voltage condition, in the memory cell in which data has been written, the inversion layer is less likely to be formed on the surface of the semiconductor substrate 11 in the vicinity of the drain region 15, due to a negative electric field of the electrons trapped in the charge storage layer 17, that is, a threshold value becomes high. Thus, the data is determined by the difference between the threshold values.

In addition, the basic operations of the memory cell M1 produced by the above production condition can be performed in voltage conditions shown in Table 1.

TABLE 1

| | SEMICONDUCTOR | GATE | SOURCE | DRAIN |
|---|---|---|---|---|
| | SUBSTRATE | ELECTRODE | REGION | ELECTRODE |
| OPERATION | (V) | (V) | (V) | (V) |
| WRITING | 0 | +2-+8 | 0 | +2-+8 |
| ERASING | 0 | −8-−2 | FLOATING | +1-+5 |
| READING | 0 | +1-+3 | +1-+3 | 0 |

### Second Embodiment

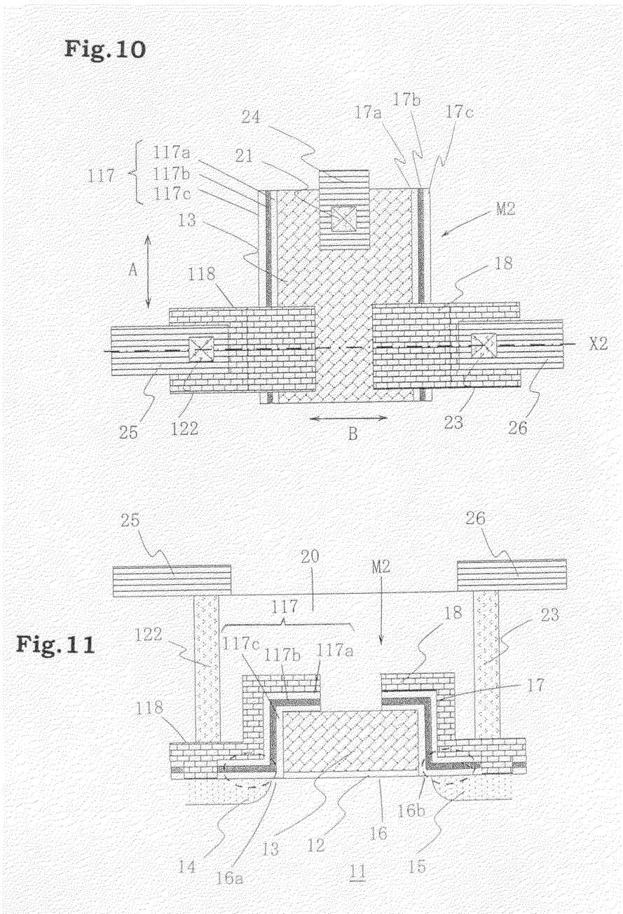

FIG. 10 is a plan view showing a second embodiment of a nonvolatile semiconductor memory device including a nonvolatile memory cell according to the present invention, and FIG. 11 is a vertical cross-sectional view taken along a line X2 in FIG. 10. In FIGS. 10 and 11, like references are given to like components as in FIGS. 1 and 2.

In a memory cell M2 according to the second embodiment, the charge storage layer and the charge storage layer electrode described in the first embodiment are arranged on each side of the gate electrode 13. That is, the memory cell M2 is a memory cell with two-bit memory capacity, including a charge storage layer 117 and a charge storage layer electrode 118 on the side of the other diffusion layer 14, in addition to the charge storage layer 17 and the charge storage layer electrode 18 on the side of the one diffusion layer 15 provided similarly to the first embodiment 1.

According to the second embodiment, the rest is roughly the same as that of the first embodiment.

Since laminated structures, materials, film thicknesses, shapes, and sizes of the charge storage layer 117 and the charge storage layer electrode 118 on the side of the diffusion layer 14 are the same as those of the charge storage layer 17 and the charge storage layer electrode 18 on the side of the diffusion layer 15, respectively, the memory cell M2 and the semiconductor memory device including the memory cell M2 have a symmetrical structure with respect to a surface positioned in the center of the channel length direction B.

Production and operations (writing, erasing, and reading) of the memory cell M2 can be performed according to the production method and the operations described in the first embodiment.

In addition, in FIGS. 10 and 11, reference 117a represents a silicon oxide film, reference 117b represents a silicon nitride film, and reference 117c represents a silicon oxide film, and the silicon nitride films 17b and 117b are charge trap regions positioned in regions surrounded by dotted lines in FIG. 11.

### Third Embodiment

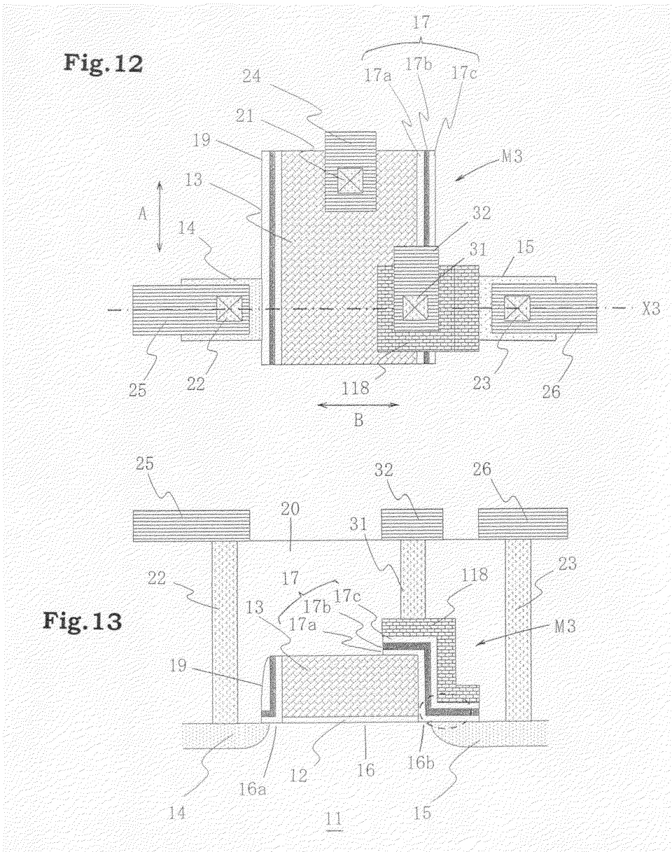

FIG. 12 is a plan view showing a third embodiment of a nonvolatile semiconductor memory device including a nonvolatile memory cell according to the present invention, and FIG. 13 is a vertical cross-sectional view taken along a line X3 in FIG. 12. In FIGS. 12 and 13, like references are given to like components as in FIGS. 1 and 2.

In a memory cell M3 according to the third embodiment, the charge storage layer electrode described in the first embodiment is electrically insulated from the impurity diffusion layer adjacent to the charge storage layer electrode, and the rest is roughly the same as that in the first embodiment.

In the memory cell M3, the charge storage layer 17 has a part overlapping the diffusion layer 15, and a length of a channel length direction B of the overlapping part is the same as the length L2 described in FIG. 6.

The charge storage layer electrode 118 is formed so as to only cover the whole surface of the charge storage layer 17 in planar view. Therefore, end surfaces of the charge storage layer electrode 118 and the charge storage layer 17 are arranged on the same position on the side of the diffusion layer 15, and the charge storage layer electrode 118 is not in contact with the diffusion layer 15.

In addition, the contact plug 23 electrically connected to the wiring 26 in the first embodiment is directly connected to the diffusion layer 15 adjacent to the charge storage layer 17 in the third embodiment.

Furthermore, in the memory cell M3, a wiring 32 used for applying a voltage to the charge storage layer electrode 118 independently is electrically connected to the charge storage layer electrode 118 through a contact plug 31.

Basic operations of the memory cell M3 in the third embodiment can be performed in voltage conditions shown in Table 2.

TABLE 2

| | | | | | CHARGE |
|---|---|---|---|---|---|
| | | | | | STORAGE |
| | SEMICONDUCTOR | GATE | SOURCE | DRAIN | LAYER |
| | SUBSTRATE | ELECTRODE | REGION | REGION | ELECTRODE |
| OPERATION | (V) | (V) | (V) | (V) | (V) |
| WRITING | 0 | +2-+8 | 0 | +2-+8 | +2-+8 |
| ERASING | 0 | −8-−2 | FLOATING | +1-+5 | −8-+5 |
| READING | 0 | +1-+3 | +1-+3 | 0 | 0 |

### Fourth Embodiment

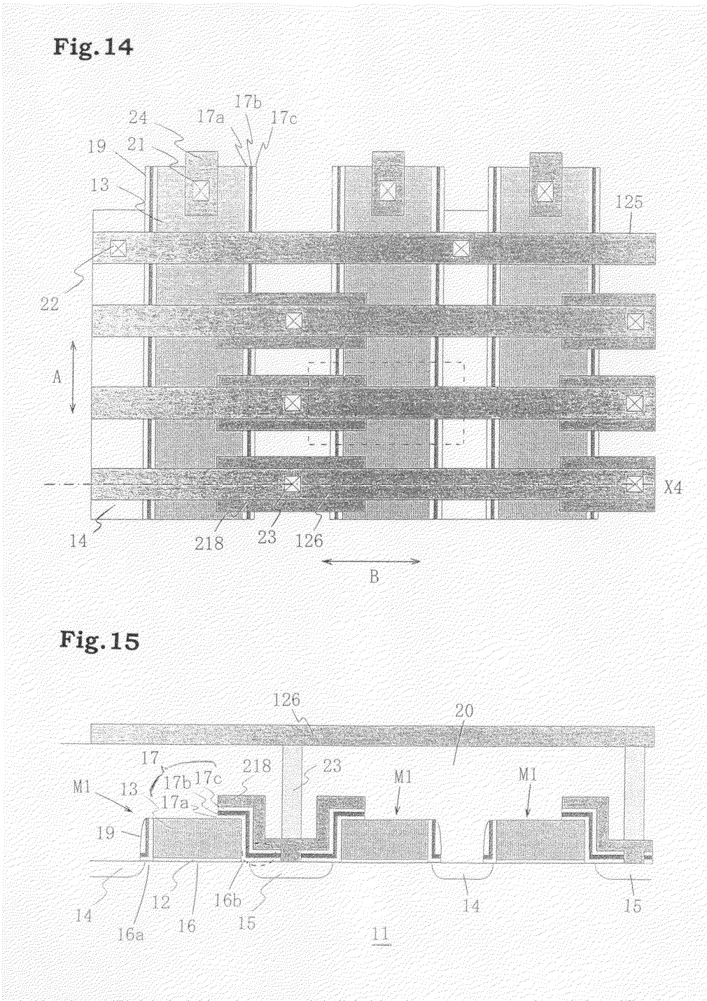

FIG. 14 is a partial plan view showing a fourth embodiment of a nonvolatile semiconductor memory device including a nonvolatile memory cell array according to the present invention, and FIG. 15 is a vertical cross-sectional view taken along a line X4 in FIG. 14. In FIGS. 14 and 15, like references are given to like components as in FIGS. 1 and 2.

This nonvolatile memory cell array (hereinafter, simply referred to as the “memory cell array” occasionally) is substantially composed of the plurality of memory cells M1 according to the first embodiment, and structure thereof will be described in detail.

The memory cell array includes the semiconductor substrate 11, a plurality of belt-like gate insulation films 12 formed in the shape of stripes on the surface of the semiconductor substrate 11, the gate electrode 13 laminated on each gate insulation film 12, the first diffusion layer (source region) 14 and the second diffusion layer (drain region) 15 formed alternately in the surface layer of the semiconductor substrate 11 on both sides of the gate electrode 13, the channel region 16 positioned in the surface layer of the semiconductor substrate 11 between the first diffusion layer 14 and the second diffusion layer 15, the charge storage layer 17 formed on the surface of the second diffusion layer 15 and along the side wall of the gate electrode 13, and a charge storage layer electrode (drain electrode) 218 laminated on the charge storage layer 17.

In addition, in FIG. 14, a region surrounded by a dotted line corresponds to the one memory cell M1.

The one gate insulation film 12 and one gate electrode 13 extend in the channel width direction A, and shared by the plurality of memory cells M1 arranged in the channel width direction A.

In addition, in each gate electrode 13, the sidewall spacer 19 is formed on the whole side wall on the side of the first diffusion layer 14, and the ONO film composed of the laminated silicon oxide film 17a, the silicon nitride film 17b, and the silicon oxide film 17c is formed on the whole side wall on the side of the second diffusion layer 15.

The charge storage layer 17 is formed by patterning the ONO film, and has a part overlapping the second diffusion layer 15 and a part overlapping the gate electrode 13.

In addition, the overlapping part of the charge storage layer 17 is separated from adjacent overlapping part of the charge storage layer 17 in the channel width direction A and the channel length direction B.

Furthermore, in FIG. 15, the silicon nitride film 17b is a charge trap region positioned in a region surrounded by a dotted line.

The first diffusion layer 14 arranged between the two adjacent gate electrodes 13 extends in the channel width direction A along the gate electrode 13, and shared by the plurality of memory cells M1 arranged in the channel width direction A.

Meanwhile, the second diffusion layer 15 arranged between the two adjacent gate electrodes 13 is separated in the channel width direction A so as to be shared by only the two memory cells M1 arranged in the channel length direction B.

Furthermore, the one charge storage layer electrode 218 is laminated on the charge storage layers 17 of the two memory cells M1 such that it straddles the adjacent gate electrodes 13 positioned on both sides of the diffusion layer 15 so as to be shared by only the two memory cells M1 which are arranged in the channel length direction B and include the above gate electrodes 13. This charge storage layer electrode 218 is provided in a groove between the charge storage layers 17 of the two memory cells M1 arranged in the channel length direction B and is electrically in contact with the second diffusion layer 15.

Thus, the semiconductor memory device having the memory cell array in which the plurality of memory cells M1 are arranged in the shape of a matrix, includes the interlayer insulation film 20 laminated on the semiconductor substrate 11 so as to cover the memory cell array, the plurality of contact plugs 21 buried in a plurality of contact holes formed in the interlayer insulation film 20 and each contact plug 21 having one end electrically connected to each gate electrode 13, the plurality of contact plugs 22 buried in a plurality of contact holes formed in the interlayer insulation film 20 and each contact plug 22 having one end electrically connected to each first diffusion layer 14, and the plurality of contact plugs 23 buried in a plurality of contact holes formed in the interlayer insulation film 20 and each contact plugs 22 having one end electrically connected to each charge storage layer electrode 218, a plurality of gate wirings 24 formed on the interlayer insulation film 20 and electrically connected to the other ends of the plurality of contact plugs 21, a source wiring 125 formed on the interlayer insulation film 20 and electrically connected to the other ends of the plurality of contact plugs 22, and a plurality of drain wirings 126 of the columns formed on the interlayer insulation film 20 and electrically connected to the other ends of the plurality of contact plugs 23 arranged in the channel length direction B.

In this case, the plurality of gate wirings 24 correspond to the word lines, respectively, and the source wiring 125 and the plurality of drain wirings 126 correspond to bit lines, respectively.

Furthermore, in the semiconductor memory device, a selection transistor (not shown) may be electrically connected to each word line and each bit line.

Production of the memory cell array of the semiconductor memory device and the operations (writing, erasing, and reading) of the memory cell M1 can be performed according to the production method and the operations described in the first embodiment.

The semiconductor memory device can considerably shorten a writing time for the whole memory cell array as compared with the memory cell array using the memory cell shown in FIG. 17.

### Fifth Embodiment

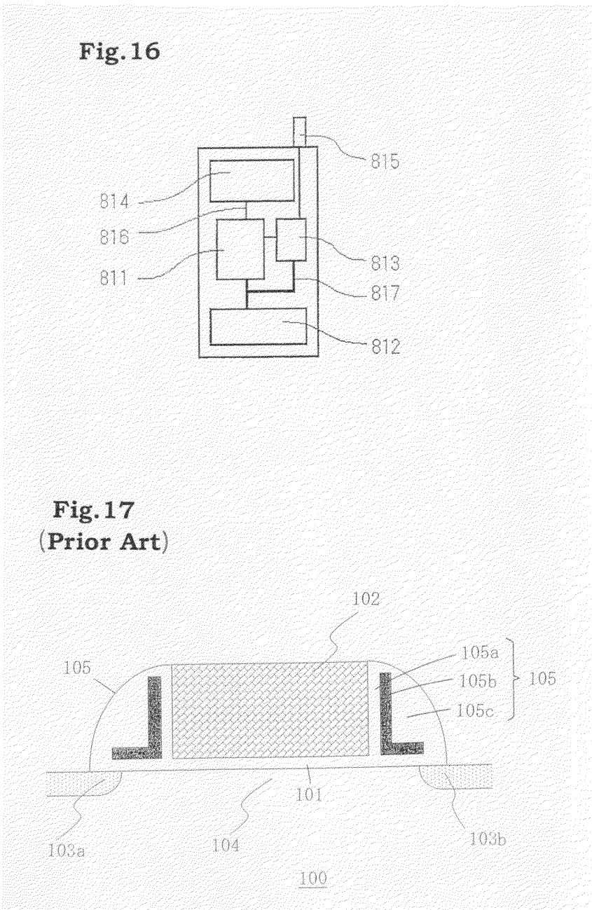

FIG. 16 is a schematic block diagram showing a mobile phone serving as a portable electronic device equipped with the nonvolatile memory cell according to the present invention.

This mobile phone is mainly composed of a control circuit 811, a battery 812, a RF (radio frequency) circuit 813, a display 814, and an antenna 815, a signal line 816, and a power supply line 817. Any of the memory cells according to the first to third embodiments is incorporated in the control circuit 811.

When this memory cell is used in the portable electronic device, a function and an operation speed of the portable electronic device can be improved and production cost can be reduced.

### Other Embodiments

1. While the semiconductor substrate and the well region are P type and the pair of impurity diffusion layers and the charge storage layer electrode are N type in the first embodiment, the conductivity types of the P type and N type may be reversed.

2. While the array structure of the memory cell according to the first embodiment has been described in the fourth embodiment, an array structure can be made with the memory cell according to the second or third embodiment.

In an array structure using the memory cell according to the second embodiment, while the first diffusion layer 14 is also shared by only the adjacent memory cells in the channel length direction like the second diffusion layer 15, and the first diffusion layers arranged in the channel length direction are connected to the same wiring, the adjacent first diffusion layers 14 in the channel width direction are connected to the different wirings, so that the number of the wirings is two times as large as the wiring number in the fourth embodiment. Therefore, it is preferable the structure is a multilayer structure to prevent the wiring of the first diffusion layer from being brought in contact with the wiring of the second diffusion layer. In addition, in the memory cell array with the memory cell according to the second embodiment, double memory capacity can be provided as compared with that of the memory cell array according to the fourth embodiment.

In an array structure with the memory cell according to the third embodiment, it is necessary to provide a wiring to be connected to the charge storage layer electrode of each memory cell. In this case, while the charge storage layer electrodes arranged in the channel length direction are connected to the same wiring, the adjacent charge storage layer electrodes arranged in the channel width direction are connected to the different wirings, so that the number of the wirings is two times as large as the wiring number in the fourth embodiment. Therefore, it is preferable that the structure is a multilayer structure to prevent the wiring of the drain electrode from being brought in contact with the wiring of the second diffusion layer.

3. While the above embodiments show the case where the charge storage layer electrode laminated on the charge storage layer is electrically connected to the impurity diffusion layer or the case where it is independently arranged, it may be electrically connected to the gate electrode. In this case, while the same voltage as that applied to the gate electrode is applied to the charge storage layer electrode, the operations (writing especially) of the memory cell can be also performed at high speed in this way.

The nonvolatile memory cell according to the present invention can be widely applied to various kinds of integrated circuits and electronic devices by combining with another memory cell, a logic element or a logic circuit. For example, the present invention can be widely applied to an electronic device including a data processing system such as a personal computer, a notebook, a laptop, a personal assistant/transmitter, a mini-computer, a work station, a mainframe, a multi-processor computer or other type of computer system; an electronic device constituting the data processing system, such as a CPU, a memory, or a data memory device; a communication device such as a telephone, a PHS, a modem, or a router; an image display device such as a display panel or a projector; an office apparatus such as a printer, a scanner, or a copying machine; an imaging device such as a video camera or a digital camera; an entertainment device such as a game machine or a music player; an information device such as a handheld terminal, a watch, or an electronic dictionary; a car device such as a car navigation system and a car audio system; an AV device to record and reproduce information such as a moving image, a static image, or music; an electric appliances such as a washing machine, a microwave oven, a refrigerator, a rice cooker, a dishwasher, a vacuum cleaner, or an air conditioner; a healthcare equipment such as a massager, a weight scale, or a manometer; and a mobile type memory device such as an IC card, and a memory card. Especially, the present invention can be effectively applied to the portable electronic device such as a mobile phone, a handheld terminal, an IC card, a memory card, a portable game machine, a digital camera, a portable moving image player, a portable music player, an electronic dictionary, or a watch. In addition, the memory cell according to the present invention may be incorporated as at least a part of a control circuit or a data memory circuit of the electronic device, or may be detachably assembled according to need.

Especially, the present invention is preferably applied to the portable electronic device and the handheld terminal by a battery.

What is claimed is:

1. A nonvolatile memory cell comprising:
a semiconductor substrate;
a gate electrode formed on a surface of the semiconductor substrate with a gate insulation film interposed between them;
a pair of impurity diffusion layers formed in a surface layer of the semiconductor substrate on both sides of the gate electrode;
a channel region positioned in the surface layer of the semiconductor substrate between the pair of impurity diffusion layers;
a charge storage layer formed on a surface of at least one impurity diffusion layer and along a side wall of the gate electrode, and
a charge storage layer electrode laminated on the charge storage layer.

2. The nonvolatile memory cell according to claim 1, wherein the charge storage layer electrode is electrically connected to the adjacent impurity diffusion layer.

3. The nonvolatile memory cell according to claim 1, wherein the impurity diffusion layer adjacent to the charge storage layer electrode is arranged apart from a region just under the gate electrode in a channel length direction, whereby an offset region is formed in the channel region.

4. The nonvolatile memory cell according to claim 3, wherein the charge storage layer electrode is formed such that the electric field is generated at least in a part of the charge storage layer which overlaps the offset region.

5. The nonvolatile memory cell according to claim 1, wherein a part of the charge storage layer overlapping the impurity diffusion layer starting from an end of the impurity diffusion layer on the side of the channel region to the channel length direction has a length of 100 to 300 nm.

6. The nonvolatile memory cell according to claim 1, wherein the charge storage layer is composed of one or more unit laminated films each having a silicon oxide film and a silicon nitride film formed in this order.

7. The nonvolatile memory cell according to claim 1, wherein the charge storage layer is composed of one or more unit laminated films each having a silicon oxide film, a silicon nitride film and a silicon oxide film formed in this order.

8. The nonvolatile memory cell according to claim 1, wherein the charge storage layer electrode is formed of polysilicon.

9. The nonvolatile memory cell according to claim 1, wherein the charge storage layer and the charge storage layer electrode are arranged on each side of the gate electrode.

10. A nonvolatile memory cell array comprising a plurality of the nonvolatile memory cell according to claim 1, wherein the charge storage layer electrode is shared by the adjacent two memory cells

11. A portable electronic device comprising the nonvolatile memory cell according to claim 1.

12. A method for producing a nonvolatile memory cell, comprising the steps of:
forming a gate electrode on a surface of a semiconductor substrate with a gate insulation film interposed between them,
forming a pair of impurity diffusion layers in a surface layer of the semiconductor substrate on both sides of the gate electrode,
forming a charge storage layer on a surface of at least one impurity diffusion layer and along a side wall of the gate electrode, and
laminating a charge storage layer electrode on the charge storage layer.

13. The method for producing a nonvolatile memory cell according to claim 12, wherein the charge storage layer electrode is formed on the charge storage layer so as to be electrically contact with the diffusion layer.

14. An operation of the nonvolatile memory cell according to claim 1, wherein applying predetermined voltages to the semiconductor substrate, the gate electrode, the pair of impurity diffusion layers, and the charge storage layer electrode, whereby writing, reading, or erasing is performed.

15. The operation of the nonvolatile memory cell according to claim 14, wherein applying same voltages to the charge storage layer electrode and its adjacent impurity diffusion layer.
